(19) United States
(12) Patent Application Publication
(10) Pub. No.: US 2026/0196986 A1
(43) Pub. Date: Jul. 9, 2026

(54) MONOLITHICALLY INTEGRATED CHALCOGENIDE SWITCH MATRIX

(71) Applicant: Dell Products L.P., Round Rock, TX (US)

(72) Inventors: Tejinder Singh, Manotick (CA); Navjot Kaur Khaira, Manotick (CA)

(21) Appl. No.: 19/013,962

(22) Filed: Jan. 8, 2025

(51) Int. Cl. H03K 3/011; H03K 17/56; H04B 1/44

(52) U.S. Cl. CPC H03K 3/011; H03K 17/56; H04B 1/44

(57) ABSTRACT

The technology described herein is directed towards a phase change material-based (e.g., chalcogenide) radio frequency switch matrix device. The switch matrix has phase change material-based switches between the device's ports, in which the phase change material switches are controlled to be in either conductive or nonconductive states, thereby respectively coupling or decoupling any port to any other port, e.g., in different operational states. A controller can selectively pulse the respective junctions of respective switches to independently determine their respective conductive or nonconductive states as needed for a specified operational state. In one implementation, the switch design is symmetrical. The phase change alloy switch device described herein provides high switching speeds, low insertion loss, good isolation and is relatively straightforward to fabricate.

### BACKGROUND

Radio frequency (RF) switches control the routing of RF signals in communication systems, and are used for tasks like antenna selection and signal path switching. Common types of RF switches include PIN diodes, FET (field effect transistor)/GaN (Gallium Nitride) switches, and MEMS (micro-electromechanical systems) switches, each with unique characteristics in terms of speed, power consumption, and performance.

RF switches are used in devices such as mobile phones, base stations, and phased array antennas for tasks like signal routing, antenna switching, and phase shifting. Important factors for RF switches include insertion loss (signal loss through the switch), isolation (preventing signal leakage between paths), and switching speed (how quickly the switch changes states). Existing RF switches often suffer from at least one of high insertion loss, poor isolation, and/or complex fabrication processes, limiting their applicability in space-constrained high-performance scenarios.

### BRIEF DESCRIPTION OF THE DRAWINGS

The technology described herein is illustrated by way of example and not limited to the accompanying figures in which like reference numerals indicate similar elements and in which:

FIG. 1 is a top view representation of an example switch layout of a switch matrix device in which switching is achieved by using phase change alloy (chalcogenide) material junctions, in accordance with various embodiments and implementations of the subject disclosure.

FIG. 2 is a top view representation of highlighting the metallic traces and switches of the example switch matrix device, in accordance with various embodiments and implementations of the subject disclosure.

FIG. 3 is a semitransparent top view representation of the example switch layout of a switch matrix device in components at the various layers are visible, in accordance with various embodiments and implementations of the subject disclosure.

FIG. 4A is a three-dimensional (3D) top perspective view representation of an example switch matrix device in which switching is achieved by using phase change alloy (chalcogenide) material junctions, in accordance with various embodiments and implementations of the subject disclosure.

FIG. 4B is a 3D side perspective view representation of an example switch matrix device in which switching is achieved by using phase change alloy (chalcogenide) material junctions, in accordance with various embodiments and implementations of the subject disclosure.

FIG. 5A is a 3D top perspective view representation of an upper portion of the example switch matrix device, in accordance with various embodiments and implementations of the subject disclosure.

FIG. 5B is a zoomed in view of part of FIG. 5A, in accordance with various embodiments and implementations of the subject disclosure.

FIG. 6 shows a schematic representation of the example four-port switch device of FIGS. 1-5 , in accordance with various embodiments and implementations of the subject disclosure.

FIG. 7A shows an example T-type switch symbol, in accordance with various aspects and implementations of the subject disclosure.

FIG. 7B shows a four-port switch example in which one of the twelve phase change material switches is depicted, in accordance with various aspects and implementations of the subject disclosure.

FIGS. 8A-8C are representations of three possible states of the example four port switch, in accordance with various embodiments and implementations of the subject disclosure.

FIGS. 9A-9C are shaded representations showing the three possible states of the example four port switch, corresponding to FIGS. 9A-9C , respectively, in accordance with various embodiments and implementations of the subject disclosure.

FIG. 10 shows example switch operational states and junction design parameters useable in the example switch device, in accordance with various embodiments and implementations of the subject disclosure.

FIG. 11 is a rendering of an example switch junction of a single port switch, in accordance with various embodiments and implementations of the subject disclosure.

FIGS. 12A, 12B, 12C, 13A, 13B, 13C and 13D (example materials) show an example manufacturing process stack usable for the switch matrix, in accordance with various embodiments and implementations of the subject disclosure.

FIG. 14A is a rendering of a crossover of the example switch matrix device, in accordance with various embodiments and implementations of the subject disclosure.

FIGS. 14B and 14C are graphical representations of performance characteristics with respect to the example crossover of FIG. 14A, in accordance with various embodiments and implementations of the subject disclosure.

FIG. 15A is a rendering of a ninety-degree bend of the example switch matrix device, in accordance with various embodiments and implementations of the subject disclosure.

FIGS. 15B and 15C are graphical representations of performance characteristics with respect to the example ninety-degree bend of FIG. 15A, in accordance with various embodiments and implementations of the subject disclosure.

FIG. 16A is a graphical representation of insertion loss versus signal frequency of an example switch matrix device, in accordance with various embodiments and implementations of the subject disclosure.

FIG. 16B is a graphical representation of isolation versus signal frequency of an example switch matrix device, in accordance with various embodiments and implementations of the subject disclosure.

FIGS. 17 and 18 comprise a flow diagram showing example operations related to electrically coupling one or more selectable RF ports to another RF port based on changing phase change alloy material junction states, in accordance with various aspects and implementations of the subject disclosure.

### DETAILED DESCRIPTION

Various implementations and embodiments of the technology described herein are generally directed towards a highly efficient, low loss, and compact radio frequency (RF) switch matrix. The switch matrix integrates chalcogenide phase-change material, enabling multistate operation for routing an input signal from any available port to any available free port, such as embodied in a four-port switch with distinct states for flexible signal routing across multiple ports.

The technology provides efficient, low-loss switching between high and low-resistance states, while reducing insertion loss and enhancing isolation. One implementation of the switch matrix features a straightforward to manufacture material stack with three metallization layers and two dielectric layers, optimizing manufacturability and monolithic integration with other RF components. Thermal management is achieved through a thermally conductive dielectric layer, allowing stable operation under varying thermal conditions. Comprehensive simulations, material characterization, and experimental data from DC to 67 GHz validate the switch device's performance, performing particularly well in the millimeter wave regime.

It should be understood that any of the examples and/or descriptions herein are non-limiting. Thus, any of the embodiments, example embodiments, concepts, structures, functionalities or examples described herein are non-limiting, and the technology may be used in various ways that provide benefits and advantages in communications and computing in general.

Reference throughout this specification to “one embodiment,” “an embodiment,” “one implementation,” “an implementation,” etc. means that a particular feature, structure, characteristic and/or attribute described in connection with the embodiment/implementation can be included in at least one embodiment/implementation. Thus, the appearances of such a phrase “in one embodiment,” “in an implementation,” etc. in various places throughout this specification are not necessarily all referring to the same embodiment/implementation. Furthermore, the particular features, structures, characteristics and/or attributes may be combined in any suitable manner in one or more embodiments/implementations. Repetitive description of like elements employed in respective embodiments may be omitted for sake of brevity.

The detailed description is merely illustrative and is not intended to limit embodiments and/or application or uses of embodiments. Furthermore, there is no intention to be bound by any expressed or implied information presented in the preceding sections, or in the Detailed Description section. Further, it is to be understood that the present disclosure will be described in terms of a given illustrative architecture; however, other architectures, structures, materials and process features, and steps can be varied within the scope of the present disclosure.

It also should be noted that terms used herein, such as “optimize,” “optimization,” “optimal,” “optimally” and the like only represent objectives to move towards a more optimal state, rather than necessarily obtaining ideal results. Similarly, “maximize” means moving towards a maximal state (e.g., up to some practical limit), not necessarily achieving such a state, and so on.

It will also be understood that when an element such as a layer, region or substrate is referred to as being “on” or “over” “atop” “above” “beneath” “below” and so forth with respect to another element, it can be directly on the other element or intervening elements can also be present. In contrast, only if and when an element is referred to as being “directly on” or “directly over” another element, are there no intervening element(s) present. Note that orientation is generally relative; e.g., “on” or “over” can be flipped, and if so, can be considered unchanged, even if technically appearing to be under or below/beneath when represented in a flipped orientation. It will also be understood that when an element is referred to as being “connected” or “coupled” to another element, it can be directly connected or coupled to the other element or intervening elements can be present. In contrast, only if and when an element is referred to as being “directly connected” or “directly coupled” to another element, are there no intervening element(s) present.

The following detailed description is merely illustrative and is not intended to limit embodiments and/or application or uses of embodiments. Furthermore, there is no intention to be bound by any expressed or implied information presented in the preceding sections, or in the Detailed Description section.

One or more example embodiments are now described with reference to the drawings, in which example components, graphs and/or operations are shown, and in which like referenced numerals are used to refer to like elements throughout. In the following description, for purposes of explanation, numerous specific details are set forth in order to provide a more thorough understanding of the one or more embodiments. It is evident, however, in various cases, that the one or more embodiments can be practiced without these specific details, and that the subject disclosure may be embodied in many different forms and should not be construed as limited to the examples set forth herein.

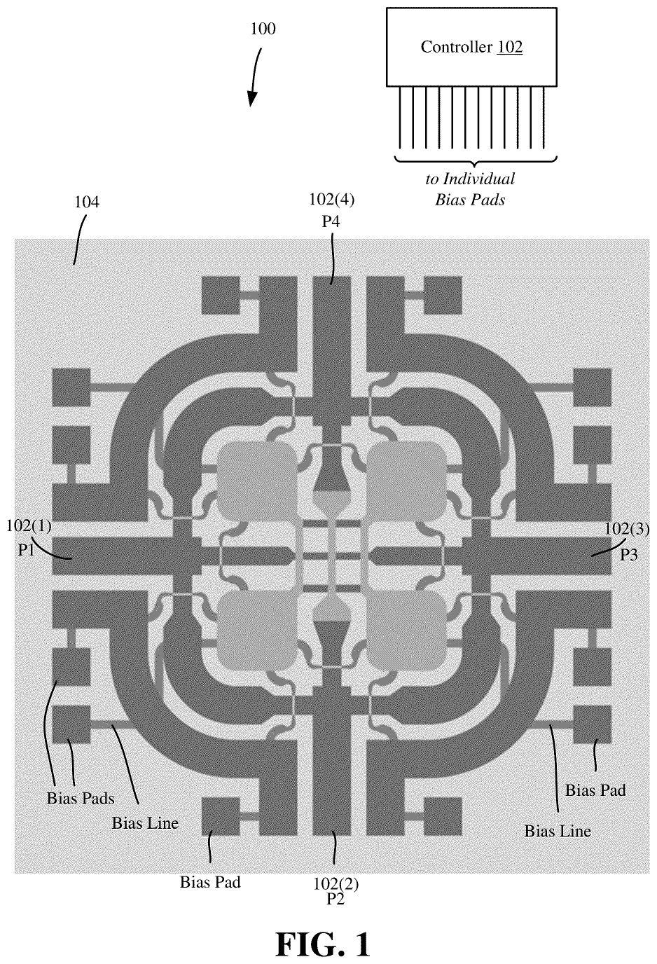

FIG. 1 shows an example top-view of one implementation of a four-port switch matrix (device) 100, including ports 102(1)-ports 102(4), also referred to as ports P1-P4, above a substrate 104. The switch matrix 100 includes bias pads (contact terminals) and bias lines, (some of which are labeled in FIG. 1) for applying voltage (or current) pulses to a heater network and thereby set the conductive or nonconductive states of the phase change material as described herein, e.g., one phase change material junction per switch. The use of conductive bias lines improves the switching time constant. A controller 102 or the like can individually pulse each heating element via its associated contact terminal.

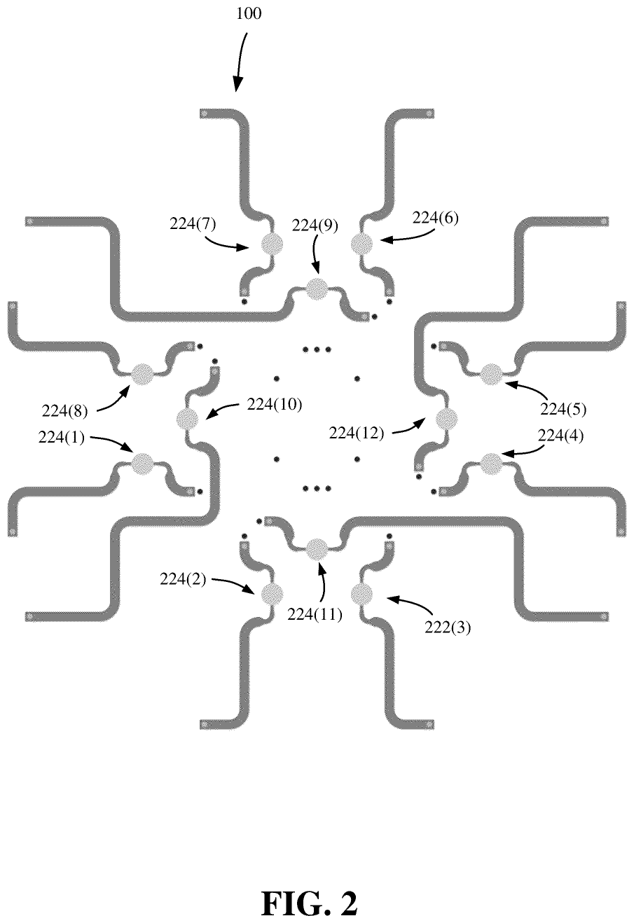

FIG. 2 shows the phase change material (PCM) switches and associated heating elements (micro heaters) labeled together in FIG. 1 as 224(1)-224(12). A phase change alloy can be deposited as the per-selectable switch junctions on a thermally conductive dielectric layer, which helps manage heat dissipation effectively, ensuring reliable operation across a wide range of thermal conditions.

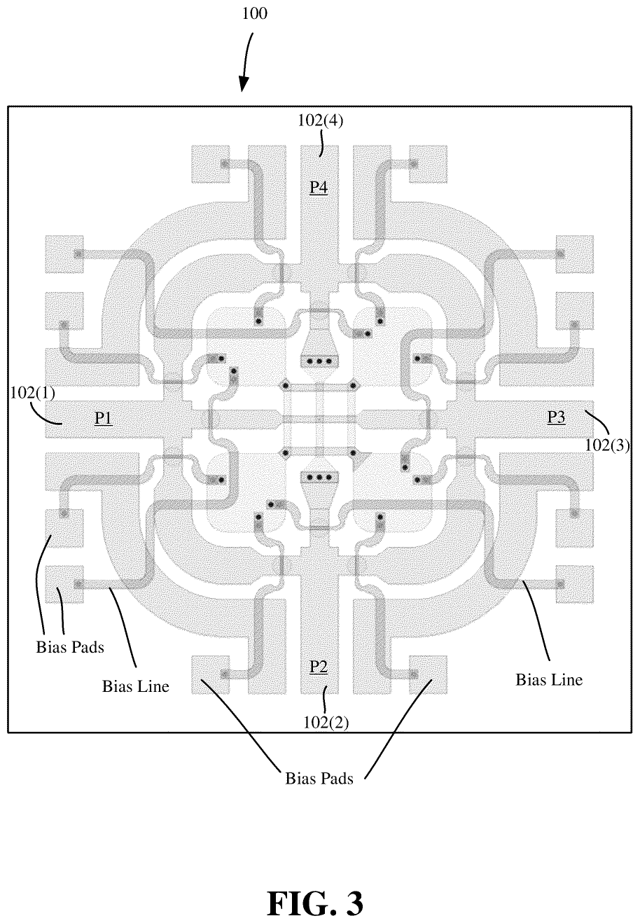

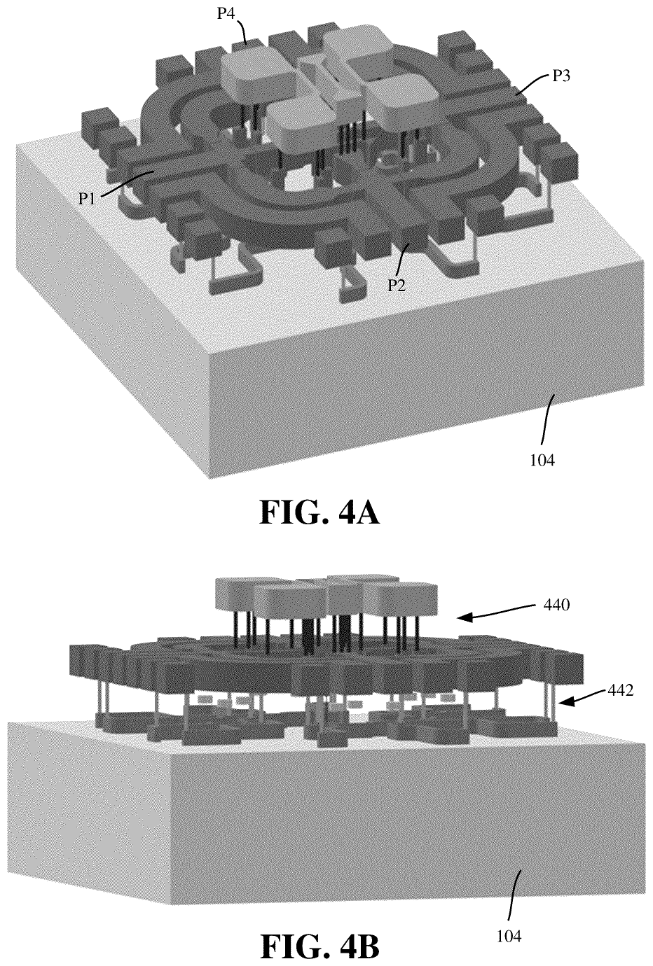

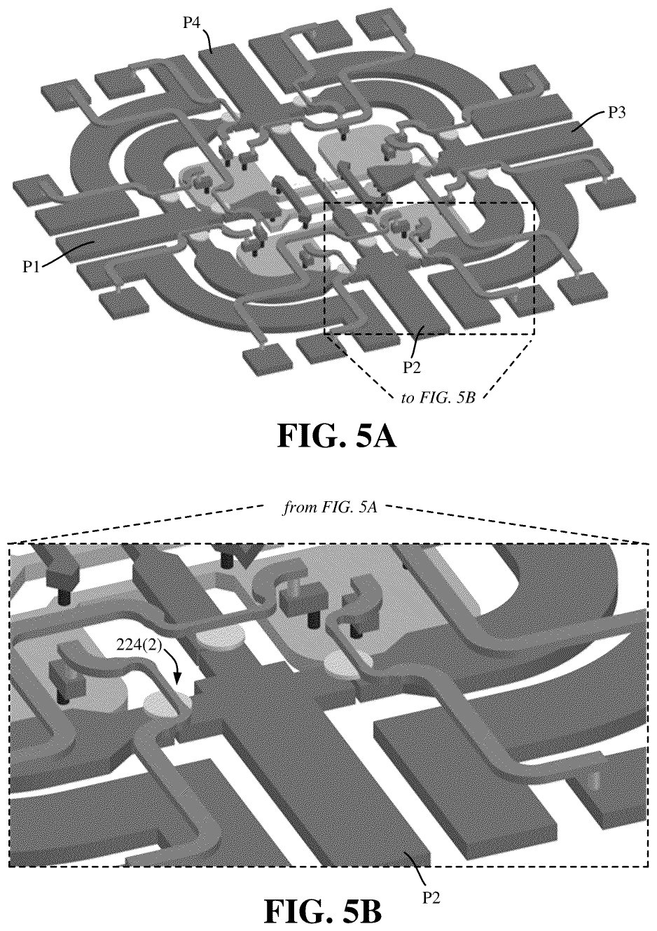

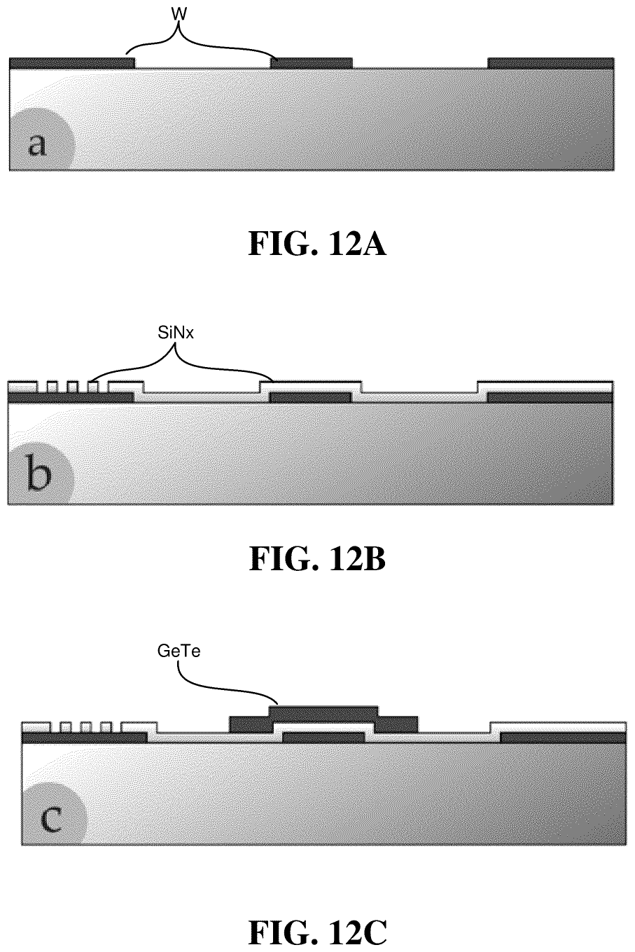

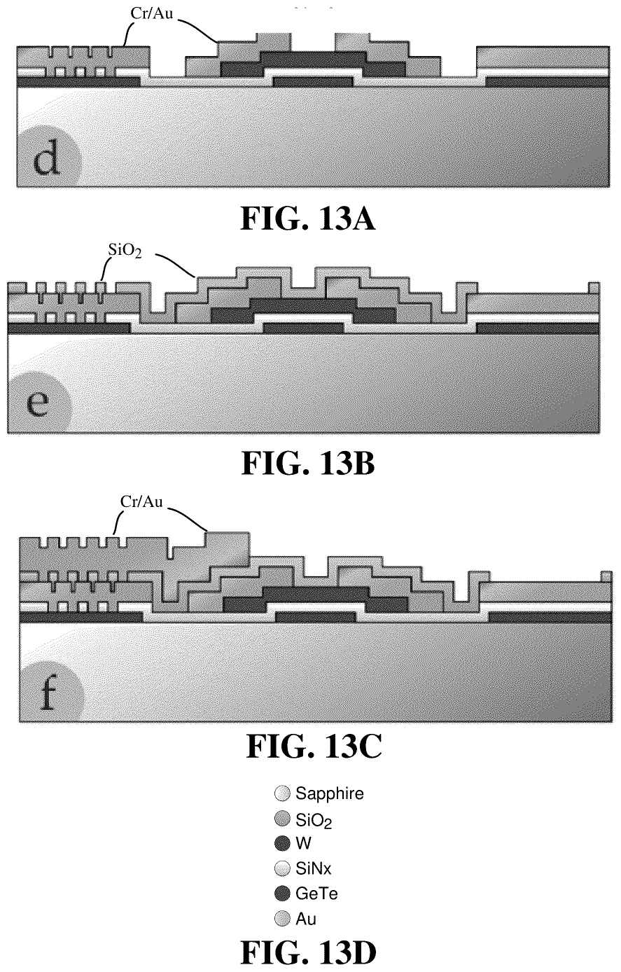

In FIG. 3, some of the metal portions and vias (represented by small black dots) are shown, which are further described with reference to FIGS. 12A-13D; FIGS. 12A-13D illustrate a scalable manufacturing process with only three metallization layers and two dielectric layers, facilitating monolithic integration with other RF components. The vias are more clearly visible in the 3D views of FIGS. 4A-and 4B, collectively labeled as 440 and 442 in FIG. 4B. The ports P1-P4 are also labeled in FIG. 5A, with FIG. 5B showing an enlarged portion of FIG. 5A that includes port P2.

Turning to the phase change junctions'individual phases, in one example implementation any of the respective ports can be coupled together or decoupled from one another based on the conductive or nonconductive states of the respective chalcogenide elements such as described in the examples herein. In general, with respect to heating phase change (chalcogenide) alloy material to change a junction's state from conductive (crystalline) state to nonconductive (amorphous) state and vice-versa, antimony telluride (SbTe) and germanium telluride (GeTe) are suitable phase change materials. GeSbTe can be tailored to offer more than six orders of magnitude change in material's resistivity with switching time on the order of sub-nanoseconds (ns), and thus provides more electrical contrast between the two states than SbTe, for example, (which offers up to four orders of magnitude change in material's resistance with switching time on the order of sub-picoseconds). GeSbTe also offers ultra-low resistance in crystalline state, offering better electromagnetic waves interaction and low resistive losses which are more prominent in SbTe.

Switching between the two states can be achieved by applying thermal energy such as a pulse with certain amplitude and width (duration on the order of nanoseconds (ns)) through an electrically insulated high-speed heater. Note that such phase change material holds its state as long as it is not actuated with another either crystalline or amorphous pulse, whereby the technology described herein offers energy-efficient switch reconfigurability, in that power is needed intermittently, that is, only during the reconfiguration phase when the heaters are actuated to change the state of the phase change material. Once the desired pattern is achieved, the material retains its state without the need for ongoing power.

For example, a medium amplitude and relatively longer duration (typically on the order of nanoseconds) SET electrical pulse of a heating element is used for crystallization during a transition to the ON state. Energy from the SET pulse heats the material for sufficient time to crystallize the material and provides adequate time for atoms to reorganize to an orderly arrangement, thus transforming from an amorphous state to crystalline state. To change to the amorphous state, a short duration (typically less nanoseconds than for the SET pulse) and high amplitude RESET electrical pulse is used. The RESET pulse provides sufficient energy to melt the material to disorder the atoms followed by rapid quenching to freeze the atoms, thus transforming the material from the crystalline state to the amorphous state. Significantly, only a short duration pulse to a heating element is needed to switch the state of the phase change material between states at the area/portion above the corresponding heating element; that is, the pulse transforms the material and latches the material into the state, without the need for continuous power in either state. The pulse duration and amplitude can be further optimized by tuning the ratio of GeSbTe alloy ratios.

The technology thus uses a phase-change chalcogenide alloy in a compact switch matrix, enabling reversible switching between multiple resistance states, minimizing insertion loss, and optimizing signal routing. This facilitates multi-state operation in which RF signals can be routed between any available ports.

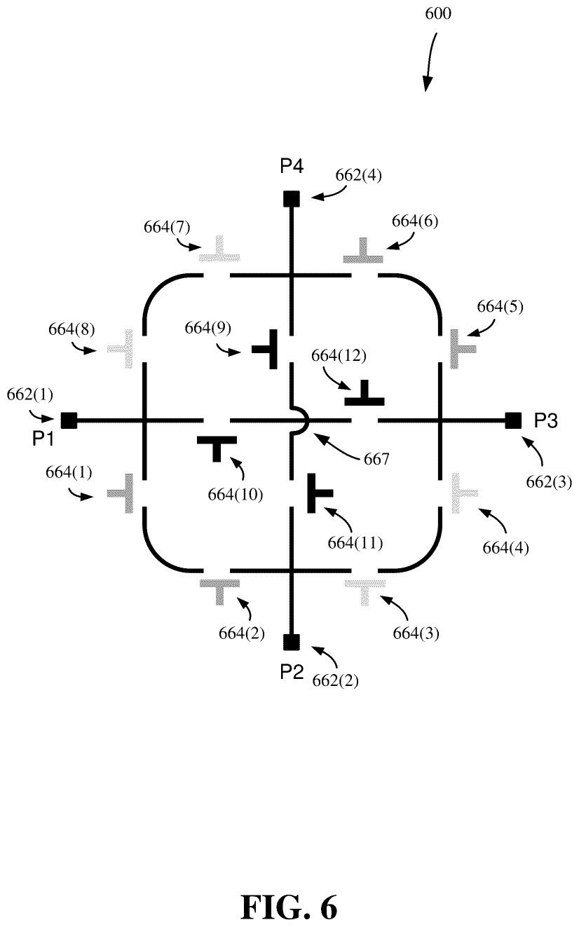

FIG. 6 shows a schematic representation 600 of the switch device 100 of FIGS. 1-5. In this example implementation, the four ports are labeled 662(1)-662(4) (and also labeled P1-P4, respectively. Twelve switches 664(1)-664(12), two per signal path between two of the ports, are controlled (set to conductive or nonconductive states/“closed” or “opened”) in order to determine which ports are coupled to which other ports. For example, when set to their conductive states, switches 664(1) and 664(12) electrically couple port P1 (222(1)) to port P3 (222(3)); similarly closing 664(1) and 664(2) couples port P1 (222(1)) port P2 (222(2)).

Note that the numbering of the ports 662(1)-662(4) and switches 664(1)-664(12) in FIG. 2 is nonlimiting and arbitrary, and is only for assisting with the description herein. Further note that while a four-port switch matrix is described, this is a nonlimiting example, and a switch matrix with more ports can be similarly configured with appropriate number of additional switches, e.g., an eight-port switch matrix, a sixteen-port switch matrix, and so on.

Also shown in FIG. 2 is a crossover (point) 667. In general, the ports 662(1)-662(4) (P1-P4) and switches 664(1)-664(12) are symmetrically distributed relative to the crossover 666 in this example implementation.

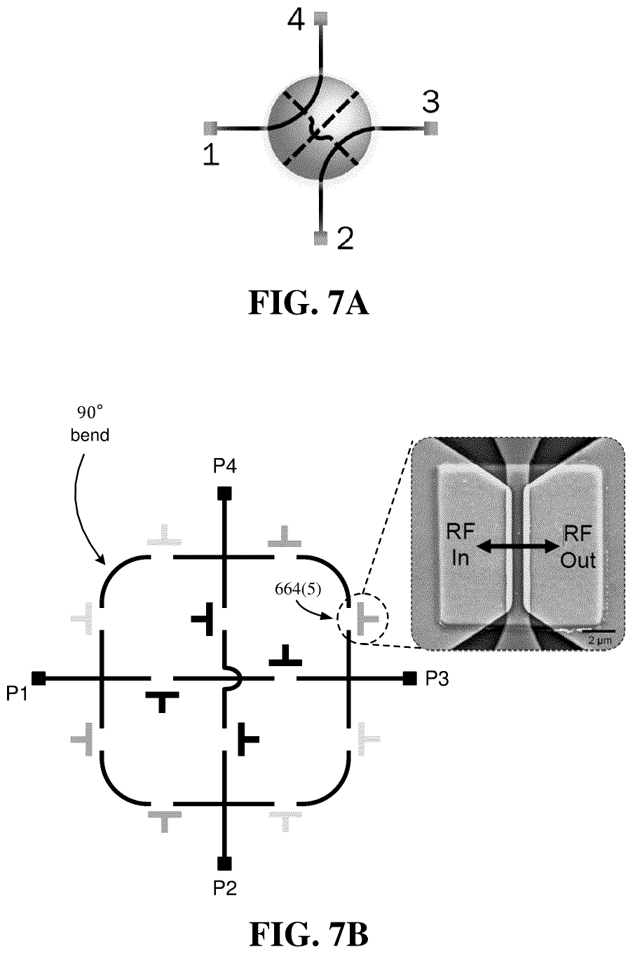

FIGS. 7A and 7B show the schematic and working principle of the switch matrix 100. An enlarged depiction of one of the switches 664(5) is shown in the upper right portion of FIG. 3B.

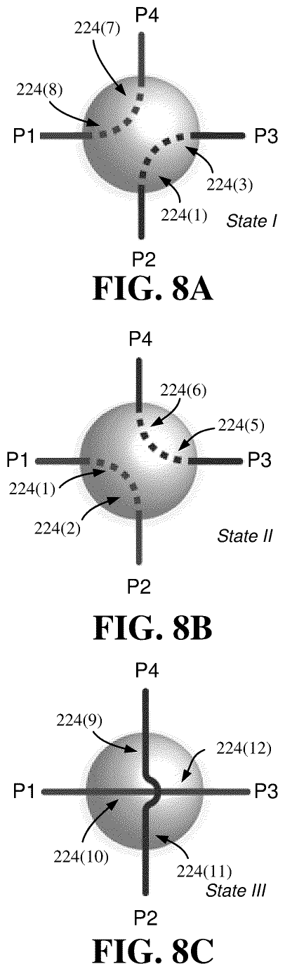

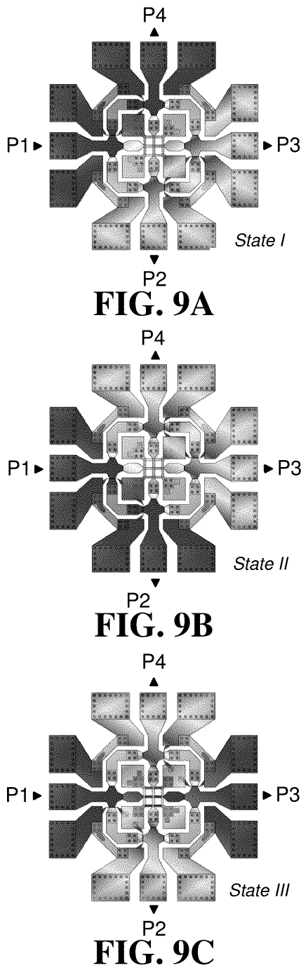

FIGS. 8A-8C, along with FIGS. 9A-9C , respectively, show three example operational non-blocking connection states, state I-state III, respectively. As can be seen, in FIGS. 8A and 9A (state I), the conductive or nonconductive states of the switches 224(7) and 224(8) determine whether port P1 is electrically coupled to or decoupled from port P4. Similarly, the conductive or nonconductive states of the switches 224(1) and 224(3) determine whether port P2 is electrically coupled to or decoupled from port P3.

In FIGS. 8B and 9B, (state II), the conductive or nonconductive states of the switches 224(1) and 224(2) determine whether port P1 is electrically coupled to or decoupled from port P2, while the conductive or nonconductive states of the switches 224(5) and 224(6) determine whether port P3 is electrically coupled to or decoupled from port P4. In FIGS. 8B and 9B, (state III), the conductive or nonconductive states of the switches 224(10) and 224(12) determine whether port P1 is electrically coupled to or decoupled from port P3 (shown as coupled/a solid line in this example), while the conductive or nonconductive states of the switches 224(9) and 224(11) determine whether port P2 is electrically coupled to or decoupled from port P4 (shown as coupled/a solid line in this example).

Note that while the example states represented in FIGS. 8A-8C and 9A-9C show possible non-blocking connections, other connections are possible. For example, port 1 can be coupled to ports 2 and 3, ports 2 and 4, ports 3 and 4, or ports 2-4 by controlling the appropriate conductive or nonconductive states of the switches 224(1)-224(12).

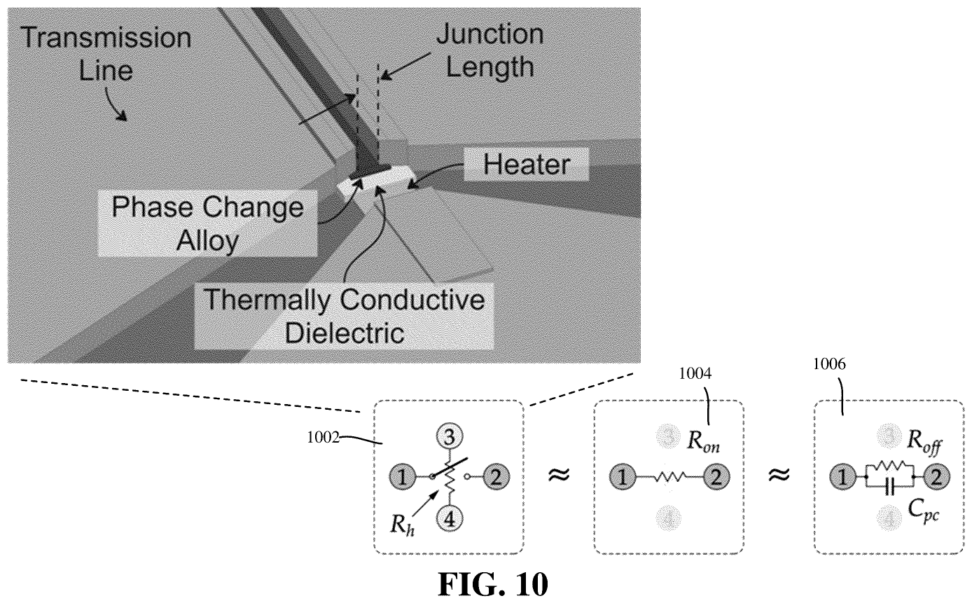

FIG. 10 shows switch operational states and junction design parameters; the switch model (block 1002) depicts the configuration, including the heater resistance Rₕ, which controls the phase transition. In the ON state (block 1004), the switch acts as a simple low-resistance path Rₒₙ, allowing RF signal transmission. In the OFF state (block 1006), the switch behaves as a high-resistance path R_{off} with additional parasitic capacitance C_{pc}, effectively blocking the RF signal.

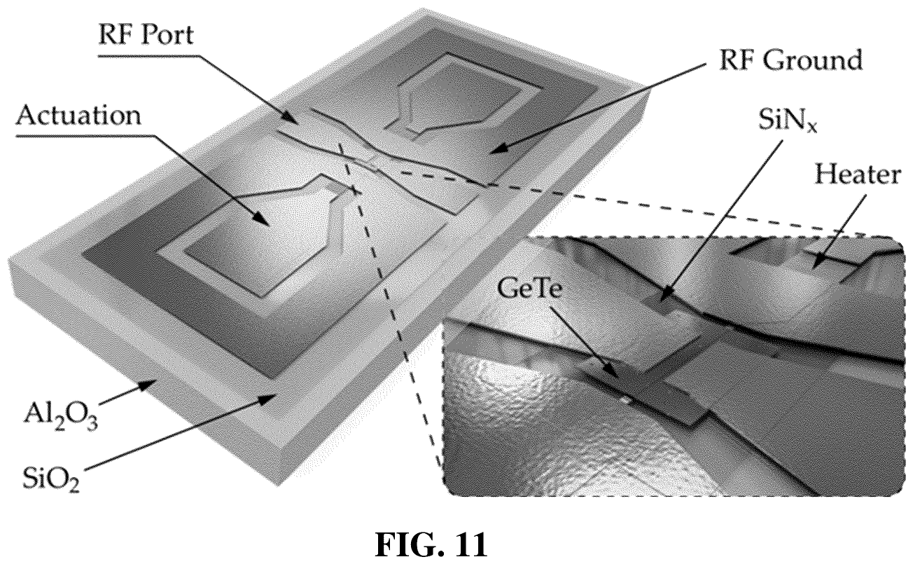

FIGS. 10 and 11 also show a single switch with an area for optimization, in which the junction of the switch and the GeTe material is highlighted. A parameter for the junction is how much gap to create between the two metal lines. In particular, if the two metals are very close to each other, along with the heater which is also a metal metallic element, parasitic capacitance is created with respect to RF signals, creating unwanted coupling that reduces isolation performance. However, keeping the metals too far away increases loss because the phase material is resistive. There is thus a balance in determining the design of the junction, including channel width, channel length, taper length, heater width and metal thickness; (e.g., the heater needs to be as narrow as possible to reduce the parasitic capacitance, but without degrading the performance).

Turning to fabrication of one such switch matrix device, FIGS. 12A-13C , along with FIG. 13D (the materials used), show how a manufacturing process stack can be constructed, beginning with FIG. 12A which shows sputtering W (Metal_0) and patterning using reactive ion etching on a sapphire/aluminum oxide substrate in crystal form (where the “W” means wire, e.g., in the form of a thin, defined metal trace. FIG. 12B shows sputtering GeTe (phase change material) and patterning using ion milling. Next, FIG. 12C shows plasma enhanced chemical vapor deposition (PECVD) of SiO2 (silicon dioxide) (for the vias Via_1) and patterning using reactive ion etching.

FIG. 13A shows PECVD of SiNx (silicon nitride) (for the vias Via_0) and patterning using reactive ion etching. FIG. 13B shows evaporating Cr/Au (chromium/gold, Metal_1) and patterning using lift-off. FIG. 13C shows evaporating Cr/Au (Metal_2) and patterning using lift-off.

Parameters for optimization include return loss, which measures how much of the input signal is reflected back towards the source due to impedance mismatches in the RF switch. Insertion loss refers to the loss of signal power that occurs when the RF signal passes through the switch. Isolation measures how well the RF switch can prevent signal leakage from one port to another when the RF switch is in the off state.

As described with reference to FIGS. 10 and 11, one such switch was designed by carefully optimizing the design parameters such as channel width, channel length, taper length, heater width and metal thickness for better return loss, insertion loss, and isolation performance. Simulations with different variations were performed in a full-field 3D electromagnetic solver.

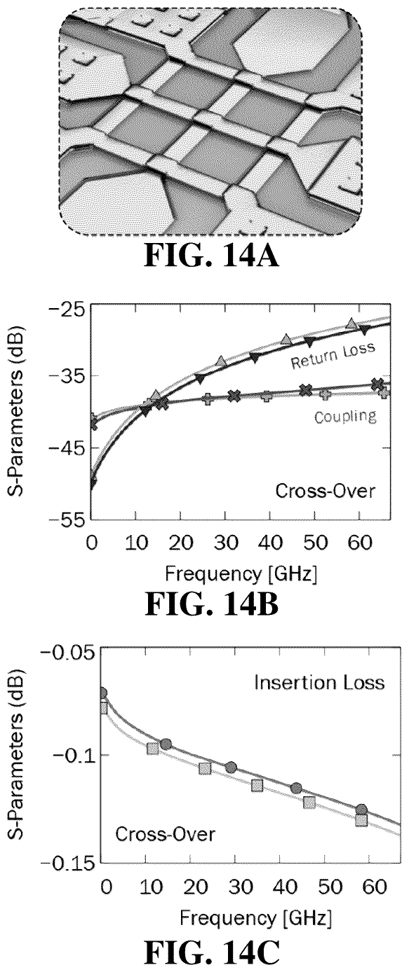

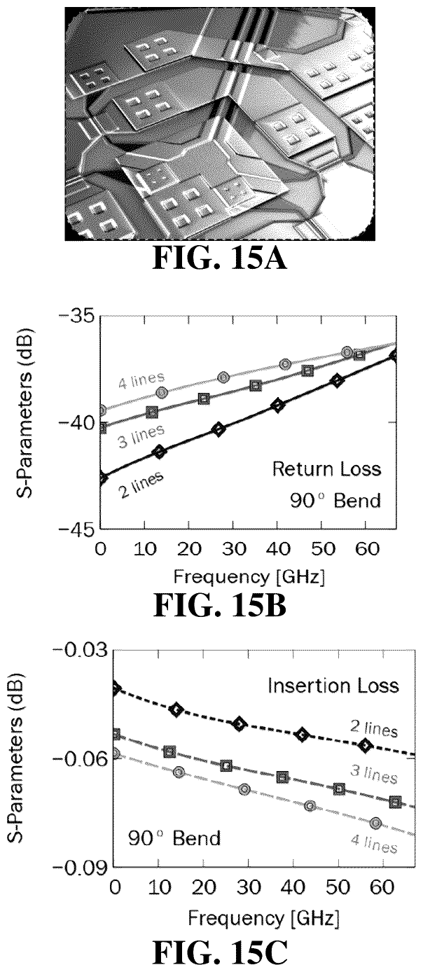

Example simulation results with respect to discontinuities (the crossover and a ninety degree (90° bend, e.g., FIG. 7B) are shown in FIGS. 14A-14C and 15A-15C, respectively.

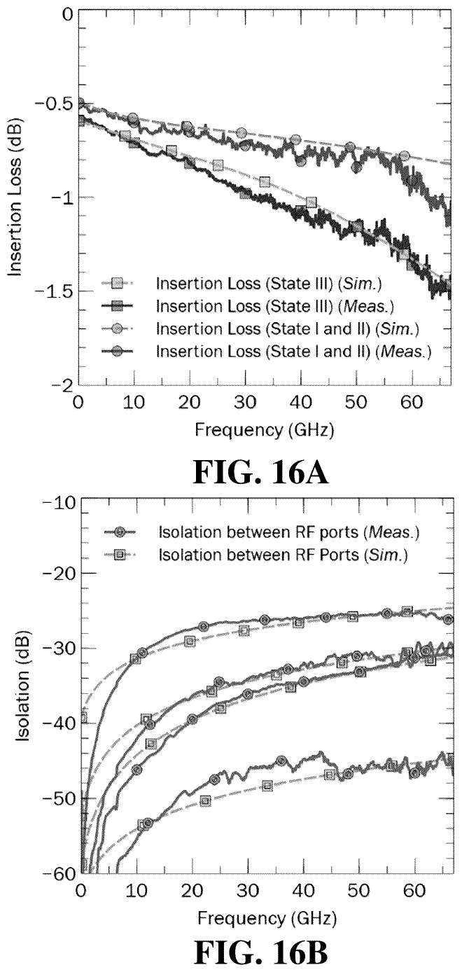

FIG. 16A graphically shows that the insertion loss of one example switch device slightly increases from −0.5 dB to −1.5 dB across 0 to 67 GHz, indicating minimal signal loss throughout the frequency range. FIG. 16B shows that return loss varies from −50 dB to −25 dB as frequency increases, demonstrating better impedance matching and reduced signal reflection at below 60 GHz frequencies. FIG. 16B shows that isolation reduces from −55 dB to −27 dB across the frequency band, which ensures effective separation of signals and minimizing interference over wideband frequencies.

One or more implementations can be embodied in a device, including a radio frequency (RF) switch matrix. The RF switch matrix can include RF ports, a group of respective selective phase change material switches coupled to the RF ports, and a controllable heater network including respective heating elements that transfer heat to the respective selective phase change material switches. The controllable heater network can be selectively controlled to output heat via energy pulses to change a subgroup of the group of respective phase change material switches to an operational state that electrically couples a first RF port to a second RF port.

The controllable heater network can be selectively controllable to change a first state of a first switch of the subgroup to a first conductive state, and to change a second state of a second switch of the subgroup to a second conductive state, to obtain the operational state that electrically couples the first RF port to the second RF port.

The operational state further can electrically couple a third RF port to a fourth RF port.

The heat can be first heat output via first energy pulses, the subgroup can be a first subgroup, the operational state can be a first operational state, and the controllable heater network can be controlled to output second heat via second energy pulses to selectively change a second subgroup of the group of respective phase change material switches to a second operational state that electrically couples the first RF port to a third RF port.

The second operational state can electrically decouple the first RF port from the second RF port.

The second operational state can electrically couple the second RF port to a fourth RF port.

The second operational state further can electrically decouple the first RF port from the second RF port.

The device further can include a crossover point that facilitates the electrically coupling of the first RF port to the third RF port, and facilitates the electrically coupling of the second RF port to the fourth RF port. The RF ports can be symmetrically distributed relative to the crossover point.

The RF ports can include a set of four RF ports, a set of eight RF ports, or a set of sixteen RF ports.

Each of the phase change material switches can include at least one of: germanium telluride or antimony telluride.

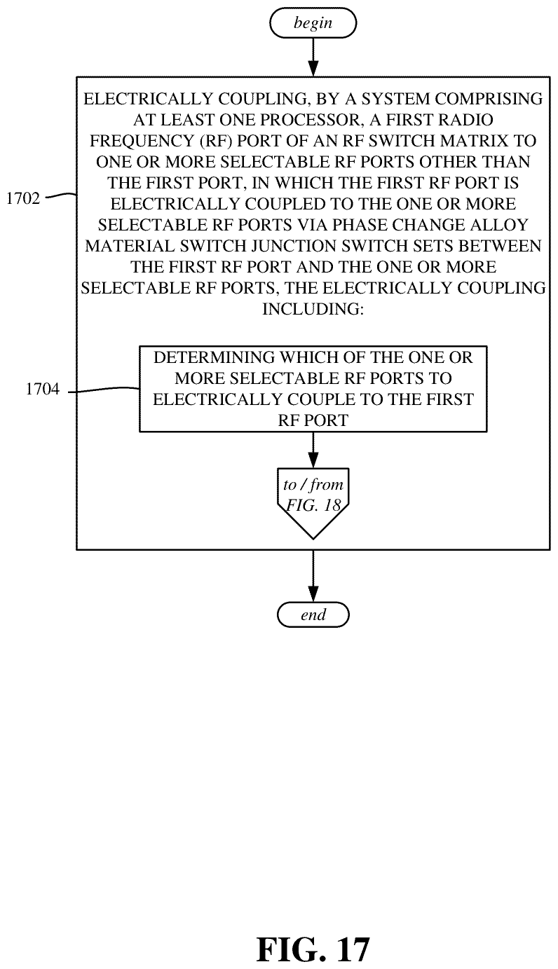

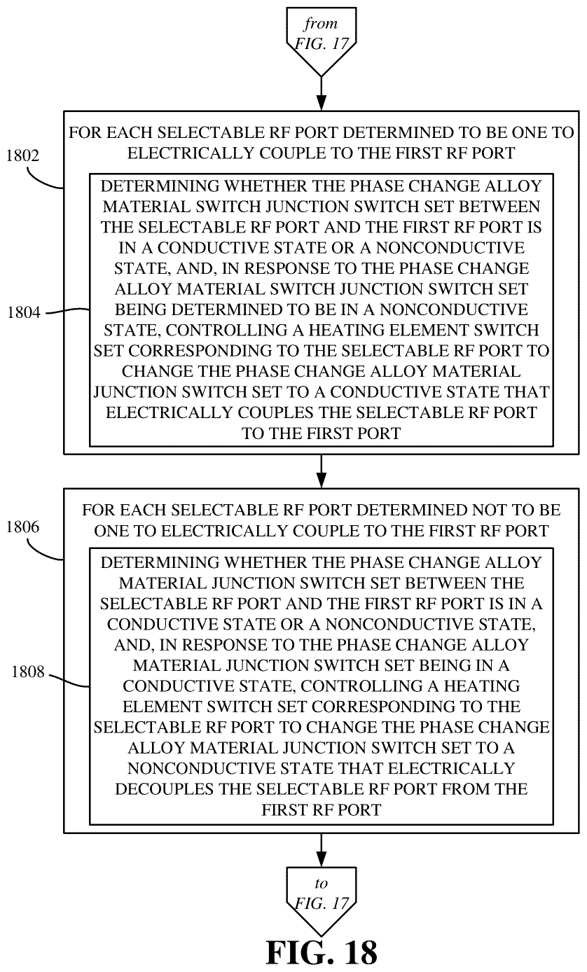

One or more example embodiments, implementations, and/or operations, such as corresponding to example operations of a method, can be represented in FIGS. 17 and 18. Example operation 1702 of FIG. 17 represents electrically coupling, by a system including at least one processor, a first radio frequency (RF) port of an RF switch matrix to one or more selectable RF ports other than the first port, in which the first RF port can be electrically coupled to the one or more selectable RF ports via phase change alloy material switch junction switch sets between the first RF port and the one or more selectable RF ports, the electrically coupling including example operation 1704. Example operation 1704 represents determining which of the one or more selectable RF ports to electrically couple to the first RF port, which includes example operations 1802-1808 of FIG. 18. Example operation 1802 of FIG. 18 represents, for each selectable RF port determined to be one to electrically couple to the first RF port, determining whether the phase change alloy material switch junction switch set between the selectable RF port and the first RF port can be in a conductive state or a nonconductive state, and, in response to the phase change alloy material switch junction switch set being determined to be in a nonconductive state, controlling a heating element switch set corresponding to the selectable RF port to change the phase change alloy material junction switch set to a conductive state that electrically couples the selectable RF port to the first port (example operation 1804). Example operation 1806 represents, for each selectable RF port determined not to be one to electrically couple to the first RF port, determining whether the phase change alloy material junction switch set between the selectable RF port and the first RF port can be in a conductive state or a nonconductive state, and, in response to the phase change alloy material junction switch set being in a conductive state, controlling a heating element switch set corresponding to the selectable RF port to change the phase change alloy material junction switch set to a nonconductive state that electrically decouples the selectable RF port from the first RF port (example operation 1808).

Controlling the heating element set can include pulsing the heating element set with a first voltage or a current pulse set to change the phase change alloy material switch junction switch set to the conductive state, or pulsing the heating element with a second voltage or current pulse set to change the phase change alloy material junction to the nonconductive state.

The first RF port can be an input port that obtains an input signal, and the electrically coupling can include determining at least one of the one or more selectable RF ports as at least one corresponding output port usable to obtain the input signal.

The first RF port can be an output port; further example operations can include determining, by the system, a single selectable RF port of the one or more selectable RF ports to be an input port that obtains an input signal, in which the electrically coupling couples the single selectable RF port to the first RF port.

The electrically coupling can be a first electrically coupling operation that couples the first RF port to a second RF port of the one or more selectable RF ports via a first phase change alloy material switch junction switch set, decouples the first RF port from a third RF port of the one or more selectable RF ports, and decouples the first RF port from a fourth RF port of the one or more selectable RF ports. Further example operations can include, in a second electrically coupling operation, electrically coupling, by the system, the third RF port to the fourth RF port via controlling a second heating element switch set associated with a second phase change alloy material switch junction switch set to change the second phase change alloy material switch junction switch set to a conductive state that electrically couples the third RF port to the fourth RF port.

One or more implementations can be embodied in a switch matrix. The switch matrix can include a group of RF ports including a first port, a second port, a third port, and a fourth port, respective phase change material switches including a first switch, a second switch, a third switch, a fourth switch, a fifth switch, a sixth switch, a seventh switch, an eighth switch, a ninth switch, a tenth switch, an eleventh switch, and a twelfth switch, and a controllable heater network. The controllable heater can include respective heating elements that transfer heat to the respective phase change material switches, in which the controllable heater network can be controlled to output heat via energy pulses to selectively determine respective lower resistance states or respective higher resistance states of the respective phase change material switches. The controllable heater network can be controlled to at least one of: set the first switch and the second switch to respective conductive states to electrically couple the first switch port to the second switch port, set the tenth switch and the twelfth switch to respective conductive states to electrically couple the first switch port to the third switch port, set the seventh switch and the eighth switch to respective conductive states to electrically couple the first switch port to the fourth switch port, set the third switch and the fourth switch to respective conductive states to electrically couple the second switch port to the third switch port, set the ninth switch and the eleventh switch to respective conductive states to electrically couple the second switch port to the fourth switch port, or set the fifth switch and the sixth switch to respective conductive states to electrically couple the third switch port to the fourth switch port.

The tenth switch and the twelfth switch can be on a first path between the first port and the third port, the ninth switch and the twelfth switch can be on a second path between the second port and the fourth port, and the first path and the second path can cross over one another at an electrically separated crossover point.

The group of RF ports can be arranged in a substantially rectangular pattern.

The first switch port can be electrically coupled to the second switch port, and the controllable heater network can be further controlled to electrically decouple the first switch port from the third switch port, and electrically decouple the first switch port from the fourth switch port.

As can be seen, the technology described herein facilitates an ultracompact switch device (switch matrix) that can be monolithically integrated. The switch matrix, based on phase-change alloy technology, can be optimized for reconfigurability, and operates efficiently from DC to 67 GHz, with superior insertion loss and isolation performance over the band. The device can be ultracompact, and can be seamlessly integrated with various RF components, such as filters, phase-shifters, attenuators, and so on, making it practical for reconfigurable RF front-ends, adaptive antenna systems, and secure networks. The phase change alloy-based RF switch overcomes the limitations of other types of RF switches, and can offer a balance between performance, reliability, and ease of manufacturing in advanced RF systems.

The RF switch, which integrates phase change alloy, facilitates efficient routing with reversible switching between high and low resistance states, minimizing insertion loss and enhancing isolation. The technology thus provides an efficient, compact, and robust switching solution, with characteristics including performance, reliability, and ease of manufacturing, that reduce or eliminate the traditional tradeoffs and limitations of traditional solutions for RF switches, such as those that rely on MEMS, PIN diodes, and GaAs-based technologies.

Example use cases include reconfigurable RF front-ends, adaptive antenna systems, and secure communication links. The switch can dynamically route signals to different antenna elements for beam steering, load balancing, and interference mitigation in 5G and next-generation wireless networks, enable frequency agility and multi-band operation in communication systems by switching between different signal paths or frequency bands, and/or create secure, encrypted communication links by dynamically altering the signal routing, making it harder for unauthorized interception. The switch can optimize signal routing in multi-beam satellite antennas, allowing for flexible communication paths based on satellite positioning and coverage needs, provide versatile signal routing for automated test setups, reducing the need for multiple dedicated switches and improving test efficiency, allow for seamless switching between different frequency bands or radar modes in advanced radar systems for military, automotive, or aerospace applications, and/or support dynamic reconfiguration of network paths in dense internet of things (IoT) environments, improving network reliability and performance.

What has been described above include mere examples. It is, of course, not possible to describe every conceivable combination of components, materials or the like for purposes of describing this disclosure, but one of ordinary skill in the art can recognize that many further combinations and permutations of this disclosure are possible. Furthermore, to the extent that the terms “includes,” “has,” “possesses,” and the like are used in the detailed description, claims, appendices and drawings such terms are intended to be inclusive in a manner similar to the term “comprising” as “comprising” is interpreted when employed as a transitional word in a claim.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A device, comprising:
a radio frequency (RF) switch matrix, comprising:
RF ports;
a group of respective selective phase change material switches coupled to the RF ports; and
a controllable heater network comprising respective heating elements that transfer heat to the respective selective phase change material switches, the controllable heater network being selectively controlled to output heat via energy pulses to change a subgroup of the group of respective phase change material switches to an operational state that electrically couples a first RF port to a second RF port.

2. The device of claim 1, wherein the controllable heater network is selectively controllable to change a first state of a first switch of the subgroup to a first conductive state, and to change a second state of a second switch of the subgroup to a second conductive state, to obtain the operational state that electrically couples the first RF port to the second RF port.

3. The device of claim 1, wherein the operational state further electrically couples a third RF port to a fourth RF port.

4. The device of claim 1, wherein the heat is first heat output via first energy pulses, wherein the subgroup is a first subgroup, wherein the operational state is a first operational state, and wherein the controllable heater network is controlled to output second heat via second energy pulses to selectively change a second subgroup of the group of respective phase change material switches to a second operational state that electrically couples the first RF port to a third RF port.

5. The device of claim 4, wherein the second operational state electrically decouples the first RF port from the second RF port.

6. The device of claim 4, wherein the second operational state electrically couples the second RF port to a fourth RF port.

7. The device of claim 6, wherein the second operational state further electrically decouples the first RF port from the second RF port.

8. The device of claim 7, further comprising a crossover point that facilitates the electrically coupling of the first RF port to the third RF port, and facilitates the electrically coupling of the second RF port to the fourth RF port.

9. The device of claim 8, wherein the RF ports are symmetrically distributed relative to the crossover point.

10. The device of claim 1, wherein the RF ports comprise a set of four RF ports, a set of eight RF ports, or a set of sixteen RF ports.

11. The device of claim 1, wherein each of the phase change material switches comprises at least one of: germanium telluride or antimony telluride.

12. A method, comprising:
electrically coupling, by a system comprising at least one processor, a first radio frequency (RF) port of an RF switch matrix to one or more selectable RF ports other than the first port, wherein the first RF port is electrically coupled to the one or more selectable RF ports via phase change alloy material switch junction switch sets between the first RF port and the one or more selectable RF ports, the electrically coupling comprising:
determining which of the one or more selectable RF ports to electrically couple to the first RF port;
for each selectable RF port determined to be one to electrically couple to the first RF port,
determining whether the phase change alloy material switch junction switch set between the selectable RF port and the first RF port is in a conductive state or a nonconductive state, and, in response to the phase change alloy material switch junction switch set being determined to be in a nonconductive state, controlling a heating element switch set corresponding to the selectable RF port to change the phase change alloy material junction switch set to a conductive state that electrically couples the selectable RF port to the first port; and
for each selectable RF port determined not to be one to electrically couple to the first RF port,
determining whether the phase change alloy material junction switch set between the selectable RF port and the first RF port is in a conductive state or a nonconductive state, and, in response to the phase change alloy material junction switch set being in a conductive state, controlling a heating element switch set corresponding to the selectable RF port to change the phase change alloy material junction switch set to a nonconductive state that electrically decouples the selectable RF port from the first RF port.

13. The method of claim 12, wherein the controlling of the heating element set comprises pulsing the heating element set with a first voltage or a current pulse set to change the phase change alloy material switch junction switch set to the conductive state, or pulsing the heating element with a second voltage or current pulse set to change the phase change alloy material junction to the nonconductive state.

14. The method of claim 12, wherein the first RF port is an input port that obtains an input signal, and wherein the electrically coupling comprises determining at least one of the one or more selectable RF ports as at least one corresponding output port usable to obtain the input signal.

15. The method of claim 12, wherein the first RF port is an output port, and further comprising determining, by the system, a single selectable RF port of the one or more selectable RF ports to be an input port that obtains an input signal,
wherein the electrically coupling couples the single selectable RF port to the first RF port.

16. The method of claim 12, wherein the electrically coupling is a first electrically coupling operation that:
couples the first RF port to a second RF port of the one or more selectable RF ports via a first phase change alloy material switch junction switch set,
decouples the first RF port from a third RF port of the one or more selectable RF ports, and
decouples the first RF port from a fourth RF port of the one or more selectable RF ports, and
further comprising:
in a second electrically coupling operation, electrically coupling, by the system, the third RF port to the fourth RF port via controlling a second heating element switch set associated with a second phase change alloy material switch junction switch set to change the second phase change alloy material switch junction switch set to a conductive state that electrically couples the third RF port to the fourth RF port.

17. A switch matrix, comprising:
a group of RF ports comprising a first port, a second port, a third port, and a fourth port;
respective phase change material switches comprising a first switch, a second switch, a third switch, a fourth switch, a fifth switch, a sixth switch, a seventh switch, an eighth switch, a ninth switch, a tenth switch, an eleventh switch, and a twelfth switch; and
a controllable heater network comprising respective heating elements that transfer heat to the respective phase change material switches, the controllable heater network being controlled to output heat via energy pulses to selectively determine respective lower resistance states or respective higher resistance states of the respective phase change material switches,
wherein the controllable heater network is controlled to at least one of:
set the first switch and the second switch to respective conductive states to electrically couple the first switch port to the second switch port;
set the tenth switch and the twelfth switch to respective conductive states to electrically couple the first switch port to the third switch port;
set the seventh switch and the eighth switch to respective conductive states to electrically couple the first switch port to the fourth switch port;
set the third switch and the fourth switch to respective conductive states to electrically couple the second switch port to the third switch port;
set the ninth switch and the eleventh switch to respective conductive states to electrically couple the second switch port to the fourth switch port; or
set the fifth switch and the sixth switch to respective conductive states to electrically couple the third switch port to the fourth switch port.

18. The switch matrix of claim 17, wherein the tenth switch and the twelfth switch are on a first path between the first port and the third port, wherein the ninth switch and the twelfth switch are on a second path between the second port and the fourth port, and wherein the first path and the second path cross over one another at an electrically separated crossover point.

19. The switch matrix of claim 17, wherein the group of RF ports are arranged in a substantially rectangular pattern.

20. The switch matrix of claim 17, wherein the first switch port is electrically coupled to the second switch port, and wherein the controllable heater network is further controlled to electrically decouple the first switch port from the third switch port, and electrically decouple the first switch port from the fourth switch port.
